(19) United States
(12) Patent Application Publication
(10) Pub. No.: US 2014/0373350 A1
(43) Pub. Date: Dec. 25, 2014

(54) Method for the Production of a Circuit Board Involving the Removal of a Subregion thereof, and Use of such a Method

(71) Applicant: AT&S Austria Technologie & Systemtechnik Aktiengesellschaft, Leoben (AT)

(72) Inventors: Markus Leitgeb, Trofaiach (AT); Gerald Weidinger, Leoben (AT); Gregor Langer, Wolfnitz (AT); Volodymyr Karpovych, Graz (AT)

(73) Assignee: AT&S Austria Technologie & Systemtechnik Aktiengesellschaft, Leoben (AT)

(21) Appl. No.: 14/363,223

(22) PCT Filed: Dec. 3, 2012
(86) PCT No.: PCT/AT2012/000303

§ 371 Date: Jun. 5, 2014

(30) Foreign Application Priority Data
Dec. 5, 2011 (AT) GM 657/2011

(51) Int. Cl. H05K 3/46

(52) U.S. Cl. CPC H05K 3/46
USPC 29/847

(57) ABSTRACT

The invention relates to a method for producing a circuit board involving the removal of a subregion thereof. In said method, at least two layers or plies of the circuit board (1) are interconnected, the subregion (6) to be removed is prevented from being connected to an adjacent ply of the circuit board by providing a layer (7) of adhesion-preventing or bonding-preventing material, and peripheral zones (8) of the subregion (6) to be removed are separated from adjoining zones of the circuit board (1). According to the invention, a fissure formation and/or a detachment from the subregion (6) of the circuit board (1) to be removed is initiated in a subregion in or on the layer (7) of adhesion-preventing or bonding-preventing material, and the subregion (6) to be removed is then removed, thus making it possible to remove a subregion (6) to be removed from a circuit board (1) in a simple and reliable, and if necessary automated, manner. Also disclosed is a use of such a method for producing a multilayer circuit board (1) and especially for creating voids in such a circuit board (1).

The present invention relates to a method for the production of a circuit board involving the removal of a subregion thereof, wherein at least two layers or plies of the circuit board are interconnected, and the subregion to be removed is prevented from being connected to an adjacent ply of the circuit board by providing or applying an adhesion-preventing or bonding-preventing material, and edge regions of the subregion to be removed are separated from adjoining regions of the circuit board. The present invention additionally relates to a use of such a method.

A method of the type mentioned in the introduction can be inferred for example from WO 2008/098269 A or WO 2008/098271 A, wherein, within the scope of production of a circuit board, it is sought to remove a subregion thereof easily and reliably, for example so as to expose an element or to form a reveal for installation of an element, in particular subsequently. Within the scope of production of a multi-ply circuit board, it is known to interconnect individual layers or plies of such a circuit board by adhesive, press or lamination methods, wherein layers or plies of this type not only have a different structure, but are usually also produced from different materials, and/or further elements, such as active or passive components, are or will be incorporated in such layers or plies. In accordance with this known method, it is sought within the scope of production of a circuit board or a circuit board intermediate product or a circuit board element to remove subregions of such a circuit board or a layer or ply following a process in which a number of layers or plies are connected, in particular so as to be able to insert further components in subsequent method steps, for example. In accordance with the known method, it is proposed to provide an adhesion-preventing or bonding-preventing material in the region of the subregion of the circuit board or a layer or ply thereof to be removed subsequently, such that, following a connection of a plurality of plies or layers of the circuit board, edge regions of the subregion to be removed are severed or separated, and, thereafter, in view of the adhesion-preventing material provided between the subregion to be removed and the adjoining or adjacent ply or layer, an easy or easier removal of this subregion is possible.

With this known method, in particular under consideration of a slight remaining adhesion between the subregion to be removed and the adjoining or adjacent layer, the subregion is removed substantially manually, wherein, in particular with use of correspondingly fine tools, it is attempted to lift or raise the sub-region and therefore to remove said subregion in the region of the severed edges. In particular under consideration of the usually small dimensions of circuit boards or circuit board elements and therefore small dimensions of a subregion to be removed and the fine structure of such circuit boards, there is a risk of damage as a result of such a manual lifting of the subregion of a circuit board to be removed, in particular to adjoining regions of the circuit board. Alternatively, in particular with flexible circuit boards, it is proposed to use bending processes to raise such a subregion to be removed, wherein, however, there is again a risk of damage to the circuit board to be produced.

The object of the invention is therefore to develop a method of the type mentioned in the introduction to the extent that the above-mentioned disadvantages or problems are avoided or at least largely reduced and in particular a subregion to be removed can be removed easily and reliably, in particular without causing damage to regions of the circuit board to be produced that adjoin said subregion.

To achieve these objects a method of the type mentioned in the introduction is basically characterised in that, a crack formation and/or a detachment from the subregion of the circuit board to be removed is induced in a subregion in or on the layer made of the adhesion-preventing or bonding-preventing material and the subregion to be removed is then be removed. Due to the fact that a crack formation and/or a detachment from the subregion to be removed is induced in or on the layer made of the adhesion-preventing or bonding-preventing material, the subregion to be removed is then removed easily and reliably, since any remaining minor adhesion or attachment between the subregion to be removed and the adjoining or adjacent layer or ply of the circuit board, at least in a subregion, is overcome as a result of the induced crack formation or detachment, and the subregion to be removed can thus be lifted or removed easily and substantially automatically. It is thus possible in particular to dispense with mechanical aids, as in the known prior art, whereby damage to the circuit board to be produced during removal of the subregion to be removed can be reliably avoided.

In conjunction with the present description, it is noted that the expression “circuit board” used herein is to denote not only a substantially finished multi-ply circuit board, but the fact that a removal, provided in accordance with the invention, of a subregion of such a circuit board can also be provided in different intermediate steps of a production process, such that the general term “circuit board” is also to be understood to mean circuit board elements or circuit board intermediate products during different method steps within the scope of production, in particular multi-step production, of a circuit board.

A particularly easy and reliable assisting of the removal of the subregion to be removed is attained in accordance with a preferred embodiment of the method according to the invention in that the crack formation and/or detachment from the subregion of the circuit board to be removed in or on the layer made of the adhesion-preventing material is/are produced by an introduction or forming of twists of the subregion to be removed, said twists being produced as a result of a non-uniform stressing of said subregion to be removed. A non-uniform stressing of this type of the subregion to be removed can be introduced into the subregion to be removed without causing damage to the circuit board to be produced, such that a lifting or detachment and removal of the subregion to be removed is assisted and/or simplified.

In accordance with a particularly preferred embodiment it is proposed in this regard for the non-uniform stresses to be introduced onto the subregion to be removed as the subregion to be removed is separated from adjoining regions of the circuit board to be removed. The machining or treatment provided with introduction of non-uniform stresses for easy removal of the subregion to be removed can thus be integrated directly in the method step of separating or severing the edge regions of the subregion to be removed from the adjoining regions of the circuit board.

To sever easily and reliably the edge regions of the subregion to be removed, it is proposed in accordance with a further preferred embodiment for the edge regions of the subregion to be removed to be defined and/or separated or severed in a manner known per se by a milling, carving or cutting, in particular laser cutting.

In this regard, it is proposed in accordance with a further preferred embodiment for a crack formation to be induced by introducing an increased mechanical stress or increased energy when the edge regions of the subregion to be removed are severed from adjoining regions of the circuit board to be removed. Again, an additional method step is or will be unnecessary for the simplified removal, sought in accordance with the invention, of the subregion to be removed, since the increased mechanical stress or increased energy can be introduced into the subregion to be removed during the severing of the edge regions of the subregion to be removed.

As already mentioned above, methods known per se can be used to implement the separation or severing of edge regions of the subregion to be removed in conjunction with a production of a circuit board. In this regard, it is additionally proposed for a laser cutting process with introduction of increased energy to be performed at least at one edge region of the subregion to be removed, as corresponds to a further preferred embodiment of the method according to the invention. Here, it is additionally preferably proposed for the increased energy to be introduced by an oscillating laser beam.

Alternatively or additionally, to induce a crack formation, it may be provided within the scope of the method according to the invention for heat energy to be fed in at one point in a substantially central region following the separation of the edge regions of the subregion to be removed from adjoining regions of the circuit board to be removed. The lifting or removal of the subregion to be removed can thus be simplified or assisted without causing damage to surrounding regions of the circuit board.

For easy removal of the subregion to be removed, it is proposed in accordance with a further preferred embodiment for the adhesion-preventing or bonding-preventing material to be formed in a manner known per se by a waxy paste, which, during a process in which at least two layers or plies of the circuit board are connected, prevents an adhesion or bonding between the subregion to be removed subsequently and the adjacent ply of the circuit board. Following a connection or coupling between the external element and the outer or external surface of the sub-region to be removed, said subregion can be removed in this way in particular with a low application of force.

For the simplification or assistance sought in accordance with the invention when removing the subregion to be removed, it is proposed in accordance with a further preferred embodiment for the waxy paste to be mixed with a propellant, which is released following a connection of at least two layers or plies of the circuit board with exposure of the subregion to be removed to a temperature that is increased compared with a temperature during the production of the connection between the layers or plies of the circuit board. A propellant of this type can be integrated easily into the waxy paste, which forms an adhesion-preventing or bonding-preventing material. Due to an additional temperature treatment of the subregion to be removed, the propellant can be released easily, and a remaining minor adhesion or attachment between the subregion to be removed and the adjoining or adjacent layer or ply of the circuit board can thus be cancelled, so as to thus remove the subregion to be removed easily and in particular without use of additional mechanical aids. In particular, due to the additional temperature treatment of merely the subregion to be removed, an impairment or damage of adjacent subregions of the circuit board is also reliably avoided.

With such a release of a propellant, the removal of the subregion to be removed can additionally be simplified or assisted since the separation or severing of edge regions of the subregion to be removed from adjoining regions of the circuit board to be removed is performed after the release of the propellant, as corresponds to a further preferred embodiment of the method according to the invention. Due to the fact that propellant contained in the waxy paste is already released, the subregion to be removed can thus be lifted and therefore reliably removed directly when separating or severing the edge regions of the subregion to be removed.

In particular under consideration of the temperatures prevailing within the scope of production of a circuit board and also the composition of the waxy paste, which forms an adhesion-preventing or bonding-preventing material, it is proposed in accordance with a further preferred embodiment of the method according to the invention for the propellant to be formed by azodicarbonamide, p-toluenesulfonyl semicarbazide or 5-phenyltetrazole.

For easy and reliable removal of the subregion to be removed following the induced crack formation or detachment or the subregion to be removed, it is additionally proposed to remove the subregion to be removed from the circuit board using an aid adhering temporarily to said subregion to be removed, for example an adhesive tape or the like, as corresponds to a further preferred embodiment of the method according to the invention.

For simplification and acceleration of the removal of a subregion to be removed, it is additionally proposed in accordance with a further preferred embodiment to remove the subregion to be removed in an automated manner.

For the simultaneous removal of a plurality of subregions to be removed from a corresponding plurality of circuit boards or circuit board elements, which are arranged for example in a common frame or support element, it is additionally preferably proposed to remove substantially simultaneously a plurality of subregions to be removed, in particular from a plurality of circuit boards, with use of a common aid.

It is additionally proposed in accordance with the invention for the method according to the invention or a preferred embodiment thereof to be implemented or used for the production of a multi-ply circuit board or a multi-ply circuit board element or circuit board intermediate product.

In particular in conjunction with such a use according to the invention, it is additionally proposed for the method according to the invention to be used to produce voids, in particular three-dimensional voids or cavities in a circuit board.

Further preferred possible uses of the method according to the invention lie in the production of at least one channel in a circuit board, a revealing of at least one element, in particular a recording element inside or in inner plies of a multi-ply circuit board, a production of recessed and/or stepped subregions of a circuit board and/or a production of a rigid/flexible circuit board.

The invention will be explained in greater detail hereinafter on the basis of exemplary embodiments of the method according to the invention illustrated schematically in the accompanying drawing, in which:

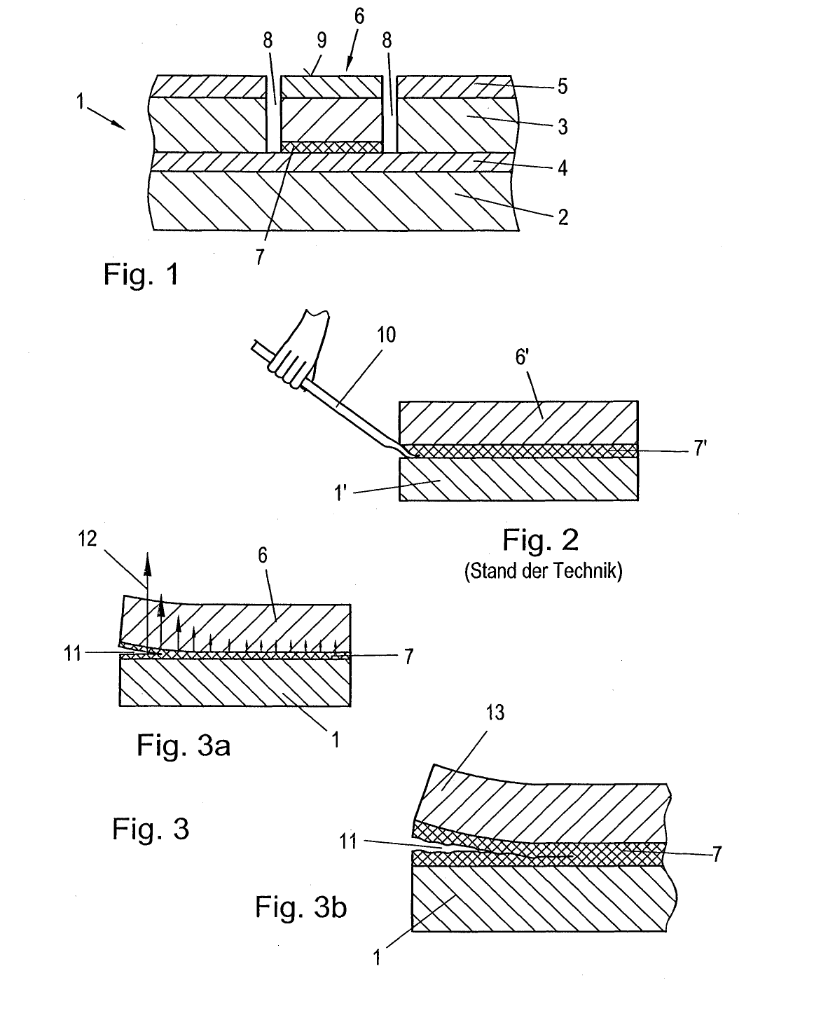

FIG. 1 shows a schematic section through a subregion of a circuit board, wherein, when carrying out the method according to the invention, edge regions of a subregion to be removed have already been severed;

FIG. 2 shows a schematic illustration according to the prior art, wherein the subregion to be removed is removed with use of a mechanical aid following the severing or the edge regions as shown in FIG. 1;

FIG. 3, schematically in accordance with the method according to the invention, shows the induction of a crack formation in the adhesion-preventing or bonding-preventing layer in a subregion beneath the subregion to be removed, wherein the introduction of a non-uniform stress for crack formation is indicated schematically in FIG. 3a, whereas in FIG. 3b a crack formation is indicated by a twisting of the subregion to be removed;

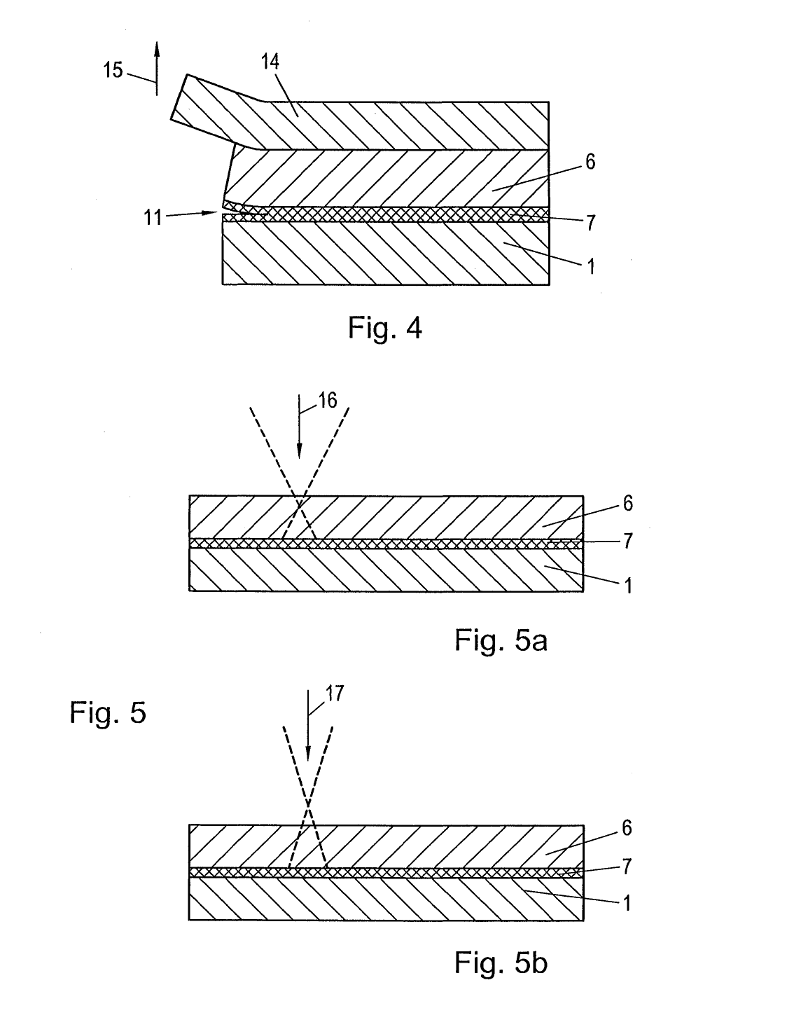

FIG. 4 shows a schematic illustration of a removal of the subregion to be removed with use of an external aid, for example in the form of an adhesive tape;

FIG. 5 shows different possibilities for an introduction of non-uniform stresses for inducing a crack formation with use of a defocussed laser beam according to the illustration of FIG. 5a or an offset laser beam according to the illustration of FIG. 5b;

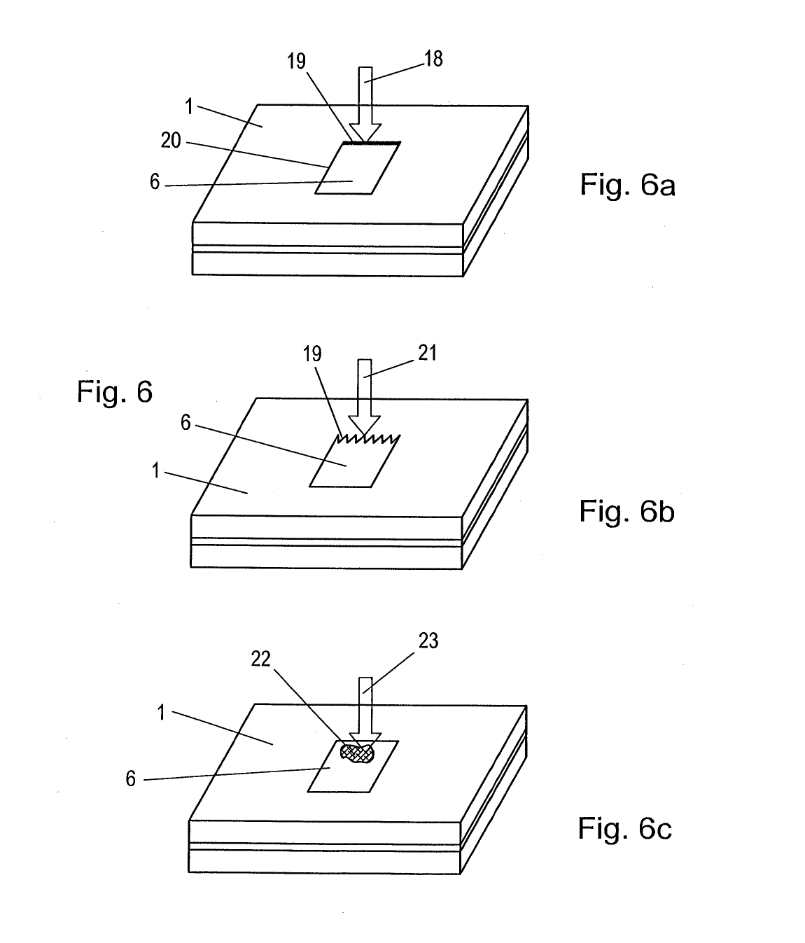

FIG. 6, similarly to the illustration of FIG. 5, shows further different embodiments of an introduction of different stresses for inducing a crack formation, wherein an increased laser energy is used in an edge region in accordance with FIG. 6a, an oscillating laser beam is used in accordance with FIG. 6b, and an additional quantity of heat is introduced into a substantially central subregion of the subregion to be removed in accordance with FIG. 6c; and

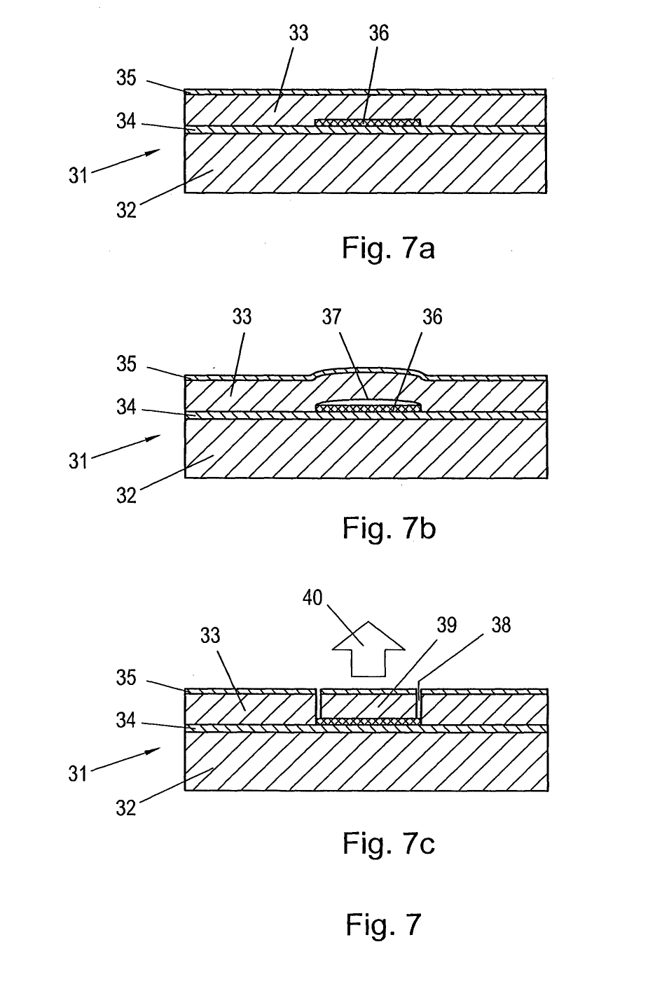

FIG. 7 shows different method steps of a further modified embodiment of the method according to the invention with use of a propellant in the adhesion-preventing or bonding-preventing material, wherein different layers or plies of a circuit board are interconnected in the method step according to FIG. 7a, the propellant contained in the adhesion-preventing or bonding-preventing material is released in a subsequent method step according to FIG. 7b, and the subregion to be removed is lifted or removed directly by the use of the propellant in a further method step according to FIG. 7c following a severing of the edge regions of the subregion to be removed.

In the method step illustrated in FIG. 1, a circuit board or a subregion thereof is denoted by 1, wherein it can be seen that the circuit board 1 is formed by a plurality of layers or plies, wherein, for example, layers 2 and 3 each consist of an insulating material, for example FR4, whereas intermediate plies 4 and 5 consist of a conducting or conductive material, in particular copper, and are optionally structured.

It is also noted that the circuit board 1 illustrated generally in FIG. 1 may represent not only a substantially finished circuit board, but also potentially a circuit board element or circuit board intermediate product, which in particular is subjected to further machining or processing steps. In addition, generally known method steps for the production of such a multi-ply circuit board and, by way of example, for structuring the conducting layers or plies 4 or 5 will not be discussed in greater detail, since these are considered to be known per se.

In FIG. 1 it is additionally shown that a subregion of the circuit board 1, said subregion being denoted generally by 6 and being intended for subsequent removal, is attached by means of an adhesion-preventing or bonding-preventing material 7 to the adjoining or adjacent layer or ply 4 during the process (not described in greater detail) for producing the multi-ply circuit board 1, such that, following a severing of the edge regions of the subregion 6 to be removed, said severing having been performed already in the illustration of FIG. 1 as indicated by the separated or severed regions 8, the subregion 6 to be removed can be easily separated from the adjoining or adjacent layer or ply 4.

For further simplification of the illustrations in subsequent FIGS. 2 to 6, the subregion 6 to be removed and also regions of the circuit board 1 or of the circuit board element adjoining said subregion to be removed are each illustrated as a one-piece element independently of a potentially provided plurality of individual layers or plies, as can be seen from FIG. 1. In addition it is noted that relative thicknesses or general dimensions of the individual elements or subregions are not illustrated true to scale, since in particular individual layers or plies have or may have an extremely low thickness compared with the dimensions of the circuit board 1 or the circuit board element or the subregion to be removed.

Additionally, in FIGS. 2 and 3, only a partial illustration is shown, wherein the subregion to be removed and an adjoining layer or ply or the circuit board are indicated in each case.

In the illustration according to FIG. 2 corresponding to the prior art it can be seen that, for a removal of a subregion to be removed, denoted by 6′, from the adjoining layer or ply of the circuit board 1′, a mechanical aid 10 is used so as to subsequently remove the subregion 6′ to be removed in the region of the adhesion-preventing or bonding-preventing layer of ply 7′ in order to overcome the minor remaining attachment or adhesion between the subregion 6′ to be removed and the circuit board 1′. It can be seen clearly that, by use of such a mechanical aid 10 and in particular under consideration of the usually low dimensions of individual elements of such a circuit board 1′, there is a direct risk of damage to regions of the circuit board 1′.

In the subsequent schematic illustrations the region beneath the subregion to be removed or adjacent to the subregion to be removed is denoted generally by 1 in accordance with the circuit board to be produced, wherein, for example, the layer or ply 2 provided in FIG. 1 is provided for this purpose.

So as to avoid such potential mechanical damage corresponding to the prior art illustrated in FIG. 2, a crack formation is thus induced in the adhesion-preventing or bonding-preventing material 7, as is indicated in FIGS. 3a and 3b by 11. Such a crack formation 11, which subsequently enables a simple removal of the subregion 6 to be removed from the circuit board 1, can be produced for example by an introduction of different stresses on the subregion 6 to be removed, as is shown schematically by the arrows 12 in FIG. 3a indicating different stresses, wherein examples for such an introduction of different stresses are illustrated in greater detail in the subsequent figures.

Alternatively or additionally, as indicated in FIG. 3b, a crack formation 11 can be induced by a twisting of an edge region 13 of the subregion 6 to be removed, whereby the subregion 6 to be removed can then likewise be removed easily from the circuit board 1 or from the underlying or adjoining layer or ply.

It is illustrated schematically in FIG. 4 that such a removal of the subregion 6 to be removed can be performed or assisted by an external aid formed by an adhesive tape 14, wherein a lifting of the adhesive tape in accordance with the arrow 15 and therefore a removal of the subregion 6 to be removed can be performed easily in particular starting from the edge region where the crack formation 11 has been induced.

In particular with an arrangement of a plurality of circuit boards or circuit board elements 1, for example in a common frame or support element (not illustrated in greater detail), as is considered to be known per se in the production of circuit boards, a plurality of subregions 6 to be removed can each be removed from a corresponding plurality of circuit boards 1 with use of such an external aid, such as an adhesive tape 14, and with use of an external aid 14 having an accordingly large surface area. Similarly, a plurality of subregions 6 to be removed can also be removed from a common circuit board or a common circuit board element 1 where necessary by use of such an external aid 14.

FIGS. 5 and 6 shows different possibilities for an introduction of different stresses, in particular into a subregion 6 to be removed, for inducing a crack formation, wherein, for simplification of the illustration, the subregion to be removed is denoted again by 6 and the circuit board is denoted again generally by 1.

In the embodiment according to FIG. 5a a laser beam 16 is used to introduce a non-uniform stress in particular in the region of a severing of an edge region of the subregion 6 to be removed, wherein the laser beam 16 is defocussed with respect to the layer or ply made of the adhesion-preventing or bonding-preventing material 7, as is illustrated in an exaggerated manner in FIG. 5a, so as to induce a crack formation (not illustrated in greater detail) in the region of the severing by use of the defocussed laser beam 16 by introducing an excessive or non-uniform stress, as indicated in FIG. 3a.

In accordance with a modified embodiment, an offset laser beam 17 is used in the illustration according to FIG. 5b, whereby a non-uniform stress is again introduced or produced in accordance with the illustration according to FIG. 3a so as to thus induce a crack formation in the region of the separation or severing to be performed by the laser beam 17.

In the embodiment according to FIG. 6a a laser beam 18 is used to introduce a non-uniform stress and, in the region of an edge region to be produced, which is denoted by 19, has increased energy compared with the other edge regions 20, as is indicated by the darker line in the region of the severing 19.

By contrast, in the embodiment according to FIG. 6b, a laser beam 21 is provided, which, in an edge region denoted again by 19, is formed by an oscillating laser beam for introduction or non-uniform stressing and therefore for induction of a crack formation, similarly to the illustration according to FIG. 3a.

In contrast to an introduction of a non-uniform stress in particular in an edge region to be severed of the subregion 6 to be removed, an excessive thermal stress compared with the other regions of the subregion 6 to be removed is provided in a central region 22 by a laser beam 23 in the embodiment according to FIG. 6c so as to thus cause a lifting in this region 22 of the subregion 6 to be removed by an induction of a crack formation due to the introduction of the additional heat energy.

A further modified embodiment is illustrated in FIG. 7, wherein a circuit board denoted generally by 31 consists again of a first insulating layer 32 and a second insulating layer 33, wherein, similarly to the illustration according to FIG. 1, copper layers 34 and 35 are additionally indicated and again can be structured. The layers of the circuit board 31 are connected to coupled, for example laminated, by known methods, wherein an adhesion-preventing or bonding-preventing layer 36 is provided in the region of a subregion to be removed subsequently and additionally contains a propellant.

Following the method steps illustrated in FIG. 7a involving a lamination of the individual layers or plies 32 to 35 of the circuit board 31 to be produced, the propellant contained in the adhesion-preventing or bonding-preventing layer 36 is released or activated by a further thermal treatment, as is indicated in an exaggerated manner by the formation of a gas bubble 37.

Following a severing of edge regions to be performed subsequently, for example by a carving, milling or laser cutting similarly to the above embodiments, as is indicated in FIG. 7c by the severed edge regions 38, the subregion 39 to be removed can be lifted or removed in accordance with the arrow 40 under consideration of the propellant provided beneath the subregion 39 to be removed.

In this embodiment too, the subregion 39 to be removed can thus be removed directly without use of mechanical aids, as is illustrated in accordance with the prior art corresponding to FIG. 2.

In particular under consideration of temperatures and pressures used within the scope of production of a circuit board 31, azodicarbonamide, p-toluenesulfonyl semicarbazide or 5-phenyltetrazole can be used, for example, as propellant.

The propellant can be contained for example in a concentration of 5% in the adhesion-preventing or bonding-preventing material 36, wherein it is released accordingly with a heating in particular of the subregion 39 to be removed to temperatures of greater than 210° C., in particular approximately 210° C. to 220° C., as is indicated in the illustration according to FIG. 7b. Here, this release or degradation temperature of the propellant is in particular slightly above temperatures for example of at most 200° C. usually used in the production or lamination of such multi-ply circuit boards 39.

Instead of a waxy bonding-preventing or adhesion-preventing material 36, which is mixed with the propellant, an adhesive or adhesive tape can also be used for example, which is arranged in the region of the subregion 39 to be removed and is likewise mixed with a propellant or degrades for example at temperatures again above 210° C. and releases a propellant for removal of the subregion 39 to be removed.

Instead of the voids to be produced, which are illustrated in the above figures and which have each substantially linear external delimitations, a recessed and/or stepped subregion can also be produced, for example by a multi-ply removal of a number of subregions to be removed in layers or plies of a multi-ply circuit board that are arranged one above the other.

1. A method for the production of a circuit board involving the removal of a subregion thereof, wherein at least two layers or plies of the circuit board are interconnected, and the subregion to be removed is prevented from being connected to an adjacent ply of the circuit board by providing a layer made of an adhesion-preventing or bonding-preventing material, and edge regions of the subregion to be removed are separated from adjoining regions of the circuit board, characterised in that, a crack formation and/or a detachment from the subregion of the circuit board to be removed is induced in an edge region in or on the layer made of the adhesion-preventing or bonding-preventing material and the subregion to be removed is then removed.

2. The method according to claim 1, characterised in that one of the crack formation and detachment from the subregion of the circuit board to be removed in or on the layer made of the adhesion-preventing material is produced by an introduction or forming of twists of the subregion to be removed, said twists being produced as a result of a non-uniform stressing of said subregion to be removed.

3. The method according to claim 2, characterised in that the non-uniform stresses are introduced onto the subregion to be removed as the subregion to be removed is separated from regions of the circuit board adjoining said subregion to be removed.

4. The method according to claim 1, characterised in that the edge regions of the subregion to be removed are defined and/or separated or severed in a manner known per se by a milling, carving or cutting, in particular laser cutting.

5. The method according to claim 1, characterised in that a crack formation is induced by introducing an increased mechanical stress or increased energy when the edge regions of the subregion to be removed are severed from regions of the circuit board adjoining said subregion to be removed.

6. The method according to claim 5, characterised in that a laser cutting process with introduction of increased energy is performed at least at one edge region of the subregion to be removed.

7. The method according to claim 6, characterised in that the increased energy is introduced by an oscillating laser beam.

8. The method according to claim 1, characterised in that, to induce a crack formation, heat energy is fed in at one point in a substantially central region following the separation of the edge regions of the subregion to be removed from adjoining regions of the circuit board to be removed.

9. The method according to claim 1, characterised in that the adhesion-preventing or bonding-preventing material is formed in a manner known per se by a waxy paste, which, during a process in which at least two layers or plies of the circuit board are connected, prevents an adhesion or bonding between the subregion to be removed subsequently and the adjacent ply of the circuit board.

10. The method according to claim 9, characterised in that the waxy paste is mixed with a propellant, which is released following a connection of at least two layers or plies of the circuit board with exposure of the subregion to be removed to a temperature that is increased compared with a temperature during the production of the connection between the layers or plies of the circuit board.

11. The method according to claim 10, characterised in that the separation or severing of edge regions of the subregion to be removed from regions of the circuit board adjoining said subregion to be removed is performed after the release of the propellant.

12. The method according to claim 10, characterised in that the propellant is formed by azodicarbonamide, p-toluenesulfonyl semicarbazide or 5-phenyltetrazole.

13. The method according to claim 1, characterised in that the subregion to be removed is removed from the circuit board using an aid adhering temporarily to said subregion to be removed, for example an adhesive tape or the like.

14. The method according to claim 1, characterised in that the subregion to be removed is removed in an automated manner.

15. The method according to claim 13, characterised in that a plurality of subregions to be removed are removed substantially simultaneously, in particular from a plurality of circuit boards, with use of a common aid.

16. Use of a method according to claim 1 for the production of at least one channel in a circuit board.

17. The use according to claim 16 for the revealing of at least one element, in particular a recording element, in the interior or in inner plies of a multi-ply circuit board.

18. The use according to claim 16 for the production of recessed and/or stepped subregions of a circuit board.

19. The use according to claim 16 for the production of a rigid/flexible circuit board.
